(19) United States
(12) Patent Application Publication
(10) Pub. No.: US 2018/0070486 A1
(43) Pub. Date: Mar. 8, 2018

(54) COMPONENT PLACING APPARATUS AND METHOD FOR PLACING COMPONENT

(71) Applicant: Panasonic Intellectual Property Management Co., Ltd., Osaka (JP)

(72) Inventors: SATOSHI ADACHI, Osaka (JP); AKIRA KAMEDA, Osaka (JP)

(21) Appl. No.: 15/691,825

(22) Filed: Aug. 31, 2017

(30) Foreign Application Priority Data
Sep. 8, 2016 (JP) 2016-175120

(51) Int. Cl. H05K 13/00; H05K 13/04; H05K 3/30

(52) U.S. Cl. CPC H05K 13/0015; H05K 13/0069; H05K 1/028; H05K 3/303; H05K 13/0404

(57) ABSTRACT

A lower surface of a center region of a board is held by a board holding table, and a lower surface of an end region (region in which a component placing region is provided) of the board is supported by a backup table. After the board holding table is moved together with the backup table and the component placing region is positioned at a working position, the placing head presses the component from above to the component placing region to place the component on the board. Meanwhile, a suction mechanism sucks an end region of the board which is supported by the backup table through a plurality of suction ports opened to an upper surface of the backup table.

### BACKGROUND

### 1. Technical Field

The present disclosure relates to a component placing apparatus that places a component on a component placing region provided in an end region of a board made of a film-shaped member.

### 2. Description of Related Art

In a component placing apparatus used in manufacture of a liquid crystal panel or the like, a component is placed (temporarily crimped) on a component placing region provided in an end region of a glass board. The component placing apparatus includes a board holding table for holding the glass board, a moving mechanism thereof, a backup stage, and a placing head. The board holding table holds a lower surface of a center region of the glass board and the moving mechanism moves the board holding table thereby positioning the component placing region of the board at a predetermined working position. The backup stage is disposed on a base so that an upper surface thereof is positioned at the working position, and supports the lower surface of the end region of the board protruding from the board holding table and positioned at the working position. The placing head picks up a component and descends from above the working position, and presses the component against the component placing region of the board of which the lower surface is supported by the backup stage, thereby placing the component on the board (see Japanese Patent Unexamined Publication No. 2016-9701).

### SUMMARY

A component placing apparatus of the disclosure is a component placing apparatus for placement of a component on a board, the board having a center region and end region in which a component placing region is provided, the apparatus including a board holding table which holds the board on a lower surface of the center region; a backup table which holds the board on a lower surface of the end region; a suction mechanism comprising suction ports opened on an upper surface of the backup table, the suction mechanism sucking the board at the end region through the suction ports; a table moving mechanism which moves both the board holding table and the backup table to position the component placing region at a predetermined working position; and a placing head which picks up the component and presses the component from above to the component placing region to place the component on the board.

According to the disclosure, it is possible to accurately place the component on the board made of the film-shaped member.

### BRIEF DESCRIPTION OF THE DRAWINGS

FIG. 1 is a perspective view of a component placing apparatus in an embodiment of the disclosure;

FIG. 2 is a side view of a part of the component placing apparatus in an embodiment of the disclosure;

FIG. 3 is a perspective view of a component placed on a board by the component placing apparatus in an embodiment of the disclosure together with the board;

FIG. 4 is a perspective view of a board holding and moving unit included in the component placing apparatus in an embodiment of the disclosure together with mark imaging cameras, the board, and the component;

FIG. 5 is a plan view illustrating a state where the board holding and moving unit included in the component placing apparatus in an embodiment of the disclosure holds the board;

FIG. 6A is a sectional side view illustrating the board holding and moving unit included in the component placing apparatus in an embodiment of the disclosure together with the board;

FIG. 6B is a sectional side view illustrating the board holding and moving unit included in the component placing apparatus in an embodiment of the disclosure together with the board;

FIG. 7A is a side view of a part of the component placing apparatus in an embodiment of the disclosure;

FIG. 7B is a side view of a part of the component placing apparatus in an embodiment of the disclosure;

FIG. 8 is a block diagram illustrating a control system of the component placing apparatus in an embodiment of the disclosure;

FIG. 9A is an explanatory view of an operation of the component placing apparatus in an embodiment of the disclosure;

FIG. 9B is an explanatory view of an operation of the component placing apparatus in an embodiment of the disclosure;

FIG. 9C is an explanatory view of an operation of the component placing apparatus in an embodiment of the disclosure;

FIG. 10 is a perspective view of a part of the component placing apparatus in an embodiment of the disclosure;

FIG. 11A is an explanatory view of an operation of the component placing apparatus in an embodiment of the disclosure;

FIG. 11B is an explanatory view of an operation of the component placing apparatus in an embodiment of the disclosure;

FIG. 11C is an explanatory view of an operation of the component placing apparatus in an embodiment of the disclosure;

FIG. 12 is a perspective view of a part of the component placing apparatus in an embodiment of the disclosure;

FIG. 13 is a perspective view of a board holding and moving unit included in a component placing apparatus in a first modification example of an embodiment of the disclosure together with mark imaging cameras, a board, and a component;

FIG. 14 is a plan view illustrating a state where the board holding and moving unit included in the component placing apparatus in the first modification example of an embodiment of the disclosure holds the board;

FIG. 15 is a perspective view of a board holding and moving unit included in a component placing apparatus in a second modification example of an embodiment of the disclosure together with a board; and

FIG. 16 is a perspective view illustrating a state where a board to which an existing board is attached is held by the board holding and moving unit included in the component placing apparatus in the second modification example of an embodiment of the disclosure.

### DETAILED DESCRIPTIONS

Prior to describing an embodiment, problems in the related art will be briefly described.

In a component placing apparatus of the related art, in a case where a board on which a component is placed is not a glass board but is made of a film-shaped member such as a flexible board, warping may occur in an end region (region where a component placing region is provided) of the board supported by a backup stage, and when a component is placed on the component placing region by a placing head, there is a problem that the component may be placed at a position shifted from a target position.

Therefore, an object of the disclosure is to provide a component placing apparatus and a method for placing a component capable of accurately placing the component on the board made of the film-shaped member.

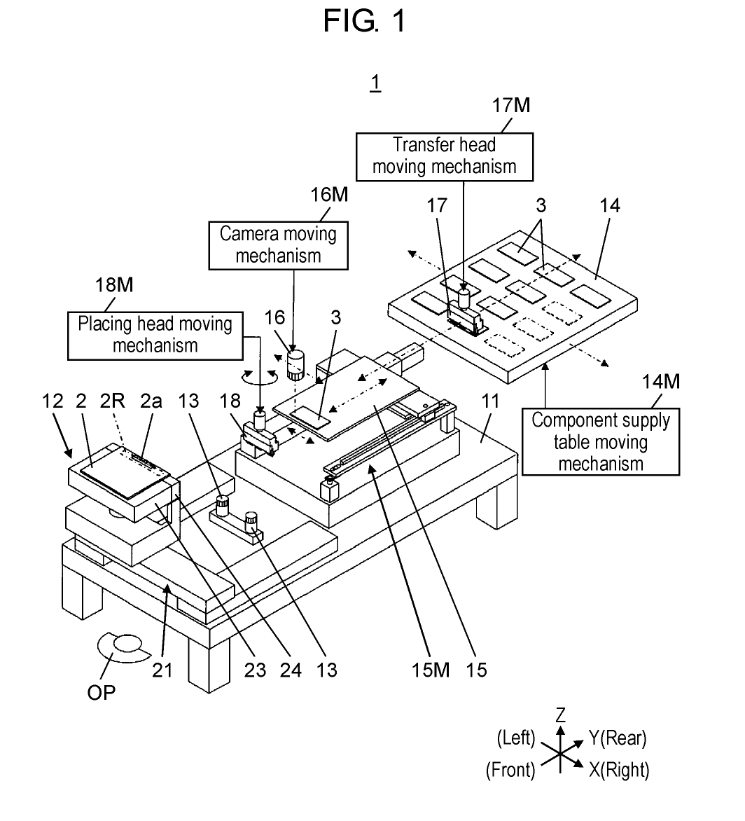

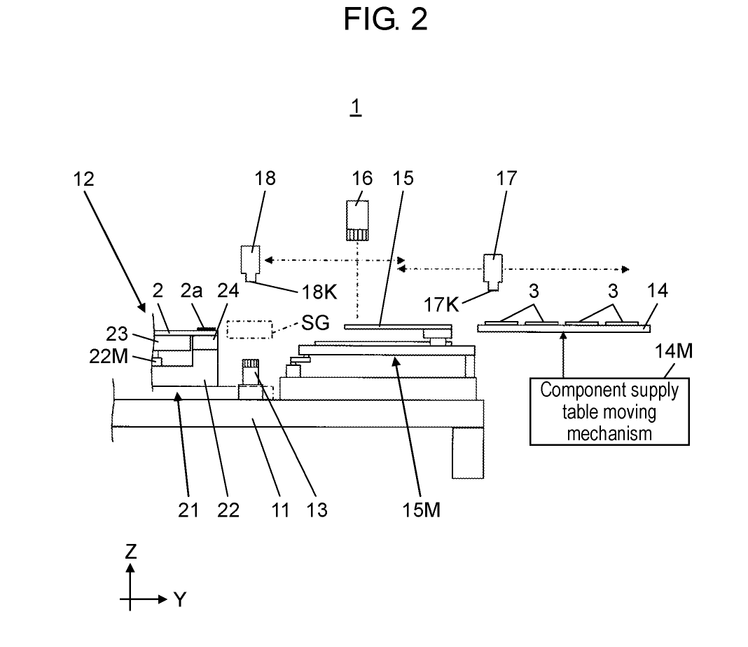

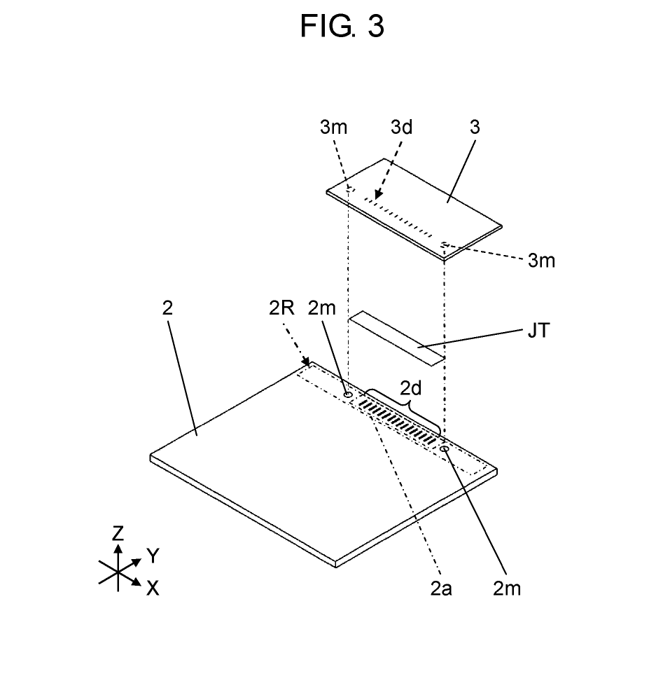

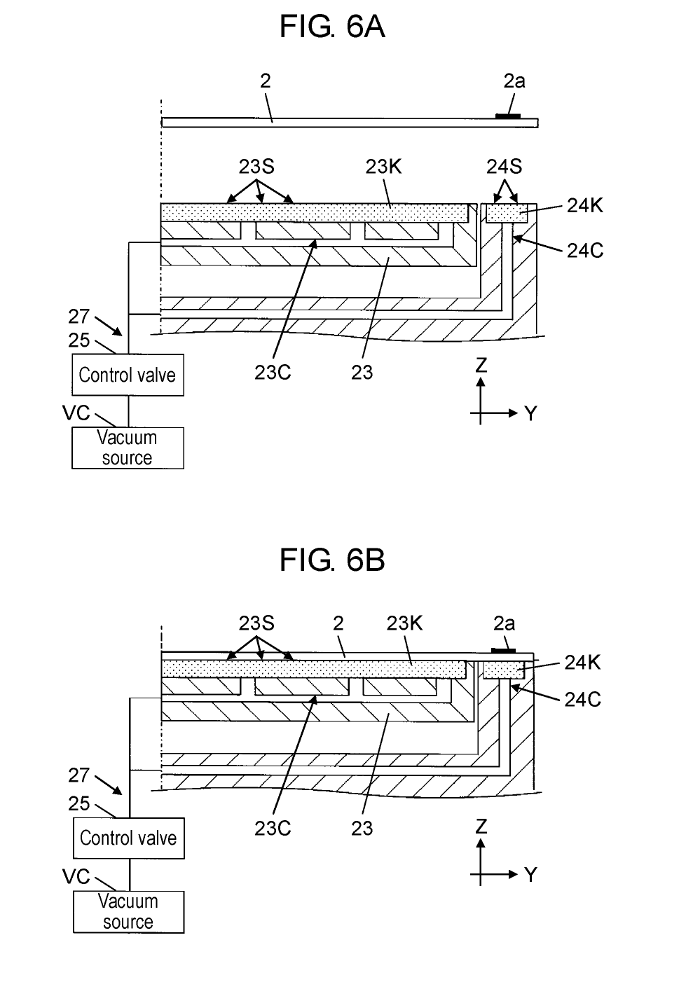

Hereinafter, an embodiment will be described with reference to the drawings. FIGS. 1 and 2 illustrate component placing apparatus 1 in the embodiment. Component placing apparatus 1 is an apparatus which places film-shaped component 3 on component placing region 2a provided in end region 2R of board 2 (for example, a flexible board) made of a film-shaped member illustrated in FIG. 3. Component placing apparatus 1 includes board holding table 23, backup table 24, suction mechanism 27 (see FIG. 6A), table moving mechanism 21, and placing head 18.

In the following description, a rightward and leftward direction viewed from operator OP is defined as an X-axis direction. A forward and rearward direction viewed from operator OP is defined as a Y-axis direction, and an upward and downward direction is defined as a Z-axis direction. A surface positioned in a positive direction of a Z-axis (direction of an arrow of a Z-axis illustrated in the drawings) is defined as an upper surface and a surface positioned in a negative direction of the Z-axis is defined as a lower surface. The positive direction of the Z-axis is defined as upward and the negative direction of the Z-axis is defined as downward.

In FIG. 3, electrode 2d is provided on the upper surface of end region 2R of board 2 and a pair of board-side marks 2m is provided at positions sandwiching both ends of electrode 2d in the X-axis direction. Electrode 2d is covered with a thermosetting resin tape JT such as an Anisotropic Conductive Film (ACF) stuck in a previous step. In the embodiment, component placing region 2a of board 2 refers to a portion (portion covered by the thermosetting resin tape JT) in which electrode 2d of end region 2R of board 2 is provided.

In FIG. 3, component terminal 3d is provided on a lower surface of a front end portion of component 3. A pair of component-side marks 3m is provided at positions sandwiching both ends of component terminal 3d in the X-axis direction. An interval between the pair of component-side marks 3m is substantially the same as an interval of the pair of board-side marks 2m provided on board 2. Therefore, in a state where two board-side marks 2m and two component-side marks 3m are aligned in a plan view, when component 3 is lowered and component 3 is pressed against board 2, electrode 2d and component terminal 3d are bonded and component 3 is placed on board 2.

In FIGS. 1 and 2, component placing apparatus 1 has board holding and moving unit 12, two mark imaging cameras 13, component supply table 14, and relay table 15 on base 11. In addition, component placing apparatus 1 is configured to include component-side mark recognition camera 16, transfer head 17, and placing head 18. Board holding and moving unit 12 is provided at a front portion (front side viewed from operator OP) of base 11, and component supply table 14 is provided at a rear portion (rear side viewed from operator OP) of base 11. Relay table 15 is provided at a position between board holding and moving unit 12 and component supply table 14 on base 11.

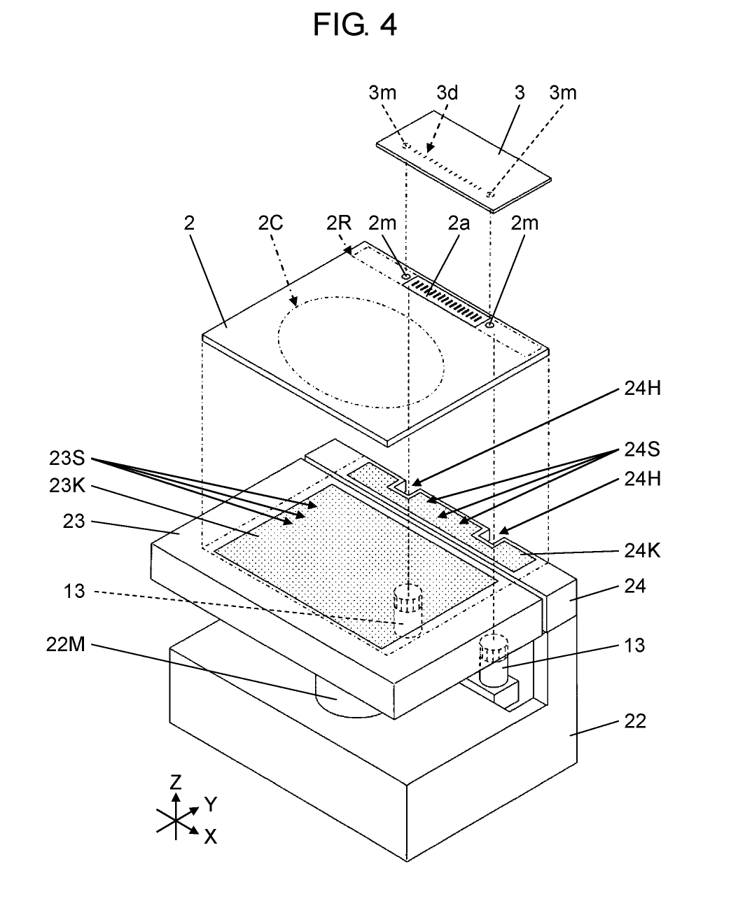

In FIGS. 1 and 2, board holding and moving unit 12 includes table moving mechanism 21 provided on base 11 and table base 22 which is moved by table moving mechanism 21 in the X-axis direction and the Y-axis direction (that is, in a horizontal plane direction). As illustrated in FIG. 4, board holding table 23 and backup table 24 are provided on table base 22. Board holding table 23 is raised and lowered with respect to base 11 by table elevation unit 22M provided on table base 22.

In FIG. 4, backup table 24 extends rearward of board holding table 23 in the X-axis direction and is provided to be fixed to table base 22. Table moving mechanism 21 moves table base 22 in the X-axis direction and the Y-axis direction, thereby integrally moving board holding table 23 and backup table 24 in the horizontal plane direction.

In FIG. 4, board holding table 23 holds a lower surface of center region 2C of board 2 supplied from the outside of component placing apparatus 1 on an upper surface thereof. Backup table 24 supports a lower surface of end region 2R of board 2 of which the lower surface of center region 2C is supported by board holding table 23.

Board holding table 23 and backup table 24 hold board 2 horizontally. Therefore, in the lower surface of the board 2, in a case where there is a step between center region 2C of board 2 supported by board holding table 23 and end region 2R of board 2 supported by backup table 24, board holding table 23 is raised and lowered with respect to (that is, with respect to backup table 24) table base 22 by operating table elevation unit 22M, thereby adjusting a height of board holding table 23 with respect to backup table 24.

In FIGS. 4, 5, 6A, and 6B, board holding table 23 has suction block 23K at the center portion thereof. An upper surface of suction block 23K is exposed in a state of being attached to board holding table 23. Suction block 23K is made of a porous material and a large number of (that is, a plurality of) suction ports 23S constituted by pores of a porous material are formed on the upper surface of suction block 23K.

In FIGS. 6A and 6B, suction pipe line 23C extends inside board holding table 23, and suction pipe line 23C is connected to suction block 23K. Suction pipe line 23C is connected to control valve 25 outside board holding table 23, and control valve 25 is connected to vacuum source VC provided outside component placing apparatus 1.

When a vacuum pressure supplied by vacuum source VC is supplied from suction pipe line 23C to suction block 23K by the operation of control valve 25, a suction force is generated on the upper surface of suction block 23K (that is, the upper surface of board holding table 23) through the plurality of suction ports 23S formed in suction block 23K. In a state where board 2 is placed on board holding table 23 (from FIG. 6A to FIG. 6B), when the suction force is generated on the upper surface of board holding table 23, center region 2C of board 2 is sucked and held on the upper surface of board holding table 23 by the suction force.

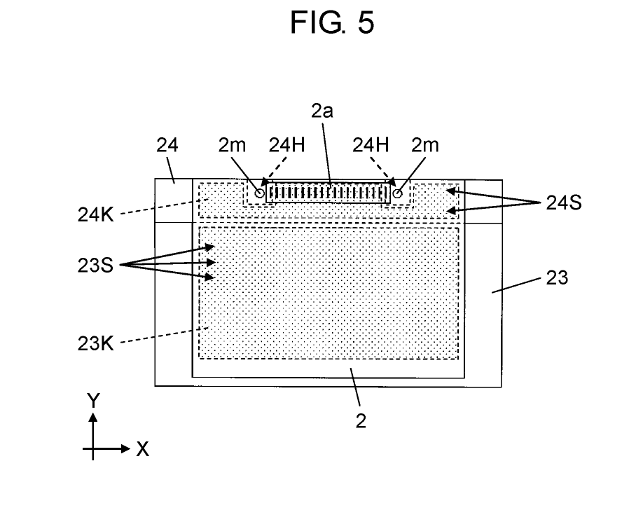

In FIGS. 5, 6A, and 6B, backup table 24 has suction block 24K at the center portion thereof. Suction block 24K is attached to backup table 24 in a state of being exposed on the upper surface. Suction block 24K is made of a porous material and a large number of (that is, a plurality of) suction ports 24S constituted by pores of a porous material are formed on the upper surface of suction block 24K. That is, the plurality of suction ports 24S are constituted by pores of a porous material provided to be exposed on the upper surface of backup table 24.

In FIGS. 6A and 6B, suction pipe line 24C extends inside backup table 24 and suction pipe line 24C is connected to suction block 24K. Suction pipe line 24C is connected to control valve 25 which is described above outside backup table 24.

The vacuum pressure supplied by vacuum source VC is supplied from suction pipe line 24C to suction block 24K by the operation of control valve 25, the suction force is generated on the upper surface of suction block 24K (that is, the upper surface of backup table 24) through the plurality of suction ports 24S formed in suction block 24K. In a state where board 2 is placed on board holding table 23 (from FIG. 6A to FIG. 6B), when the suction force is generated on the upper surface of backup table 24, end region 2R of board 2 is sucked on an upper surface side of backup table 24, and the lower surface thereof is in close contact with the upper surface of backup table 24 by the suction force.

As described above, in the embodiment, vacuum source VC, control valve 25, and suction pipe line 24C form suction mechanism 27 which sucks end region 2R of board 2 supported on backup table 24 through the plurality of suction ports 24S opened on the upper surface of backup table 24 (FIGS. 6A and 6B).

In FIGS. 4 and 5, backup table 24 has two cutout portions 24H provided at intervals between two board-side marks 2m included in board 2. Each cutout portion 24H penetrates through backup table 24 vertically. Two cutout portions 24H are provided at positions at which two board-side marks 2m included in board 2 can be viewed from below (that is, positions at which two board-side mark 2m can be taken an image of by two mark imaging cameras 13 which are described below) in a state where center region 2C of board 2 is held on board holding table 23 and end region 2R of board 2 is supported on backup table 24.

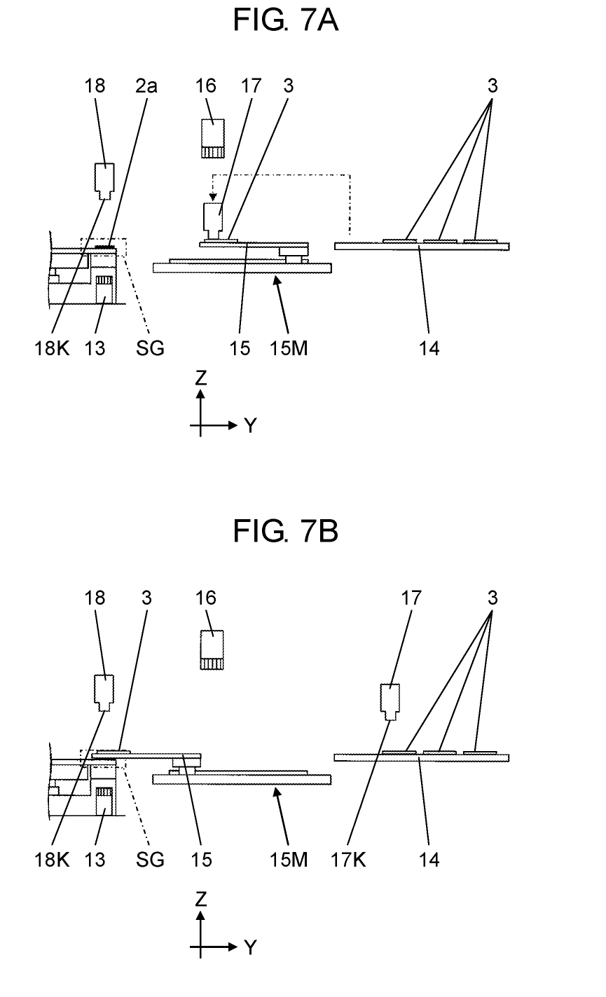

After board 2 is held by board holding table 23 and backup table 24, board holding and moving unit 12 moves table base 22 in the horizontal plane direction using table moving mechanism 21, and positions component placing region 2a of board 2 at a predetermined position (hereinafter, the position is referred to as working position SG. See FIGS. 2, 7A and 7B) of the front side of component supply table 14 (side of operator OP). In this case, since board holding table 23 and backup table 24 integrally move, board 2, which is held on the horizontal posture by board holding table 23 and backup table 24, moves in a state where the horizontal posture is held.

As described above, in the embodiment, table moving mechanism 21 moves board holding table 23 holding center region 2C of board 2 together with backup table 24 holding end region 2R of board 2 to position component placing region 2a at predetermined working position SG.

In FIGS. 1 and 2, component supply table 14 holds a plurality of components 3 in a state of being aligned. Component supply table 14 is connected to component supply table moving mechanism 14M, and component supply table moving mechanism 14M moves component supply table 14 in the horizontal plane direction.

In FIGS. 1, 2, and 4, two mark imaging cameras 13 are respectively attached to base 11 in a state where the imaging field of view faces upward. Two mark imaging cameras 13 are disposed of adjacent to each other at a lower position of working position SG in the X-axis direction, and an interval thereof is substantially equal to the interval of two component-side marks 3m (and the interval of two board-side marks 2m) (FIG. 4).

When table base 22 is moved by table moving mechanism 21 in the horizontal plane direction and component placing region 2a of board 2 is positioned at working position SG, two board-side marks 2m provided in board 2 are positioned directly above two mark imaging cameras 13. In this case, two cutout portions 24H provided in backup table 24 are also positioned directly above two mark imaging cameras 13 (FIG. 4). Therefore, each mark imaging camera 13 can take an image of board-side mark 2m positioned directly above mark imaging camera 13 through cutout portion 24H.

In FIGS. 1 and 2, relay table 15 is connected to relay table moving mechanism 15M provided on base 11. Relay table moving mechanism 15M moves relay table 15 between a first position and a second position along the Y-axis direction. Here, the “first position” is a position (FIG. 7A) where component 3 is transferred from component supply table 14 by transfer head 17 described below. The “second position” is a position (FIG. 7B) where component 3 transferred by transfer head 17 is positioned at working position SG. The second position is a position in front of the first position. Relay table moving mechanism 15M can also move relay table 15 in the X-axis direction.

In FIG. 1, the imaging field of view of component-side mark recognition camera 16 faces downward. Component-side mark recognition camera 16 is connected to camera moving mechanism 16M, and camera moving mechanism 16M moves component-side mark recognition camera 16 in the X-axis direction. Camera moving mechanism 16M moves component-side mark recognition camera 16 above component 3 placed on relay table 15 in the X-axis direction, and component-side mark recognition camera 16 takes an image of two component-side marks 3m provided adjacent to each other in the X-axis direction on the upper surface of component 3 placed on relay table 15 from above.

In FIG. 2, transfer head 17 includes component suction port 17K sucking component 3 at a lower end. Transfer head 17 is connected to transfer head moving mechanism 17M (FIG. 1), and transfer head moving mechanism 17M moves transfer head 17 in the Y-axis direction and the Z-axis direction. Transfer head 17 moves between an upper region of component supply table 14 and an upper region of relay table 15, thereby transferring component 3 supplied from component supply table 14 to relay table 15 positioned at first position (FIG. 7A. Details will be described later).

In FIG. 2, placing head 18 includes component suction unit 18K sucking component 3 at the lower end. Placing head 18 is connected to placing head moving mechanism 18M (FIG. 1). Placing head moving mechanism 18M moves placing head 18 in the Z-axis direction, or rotates placing head 18 around the Z-axis. Placing head 18 is raised and lowered above working position SG thereby sucking and picking up component 3 from relay table 15 (FIG. 7B) positioned at the second position. After relay table 15 moves rearward, placing head 18 is lowered thereby pressing component 3 against component placing region 2a to place component 3 (details will be described later).

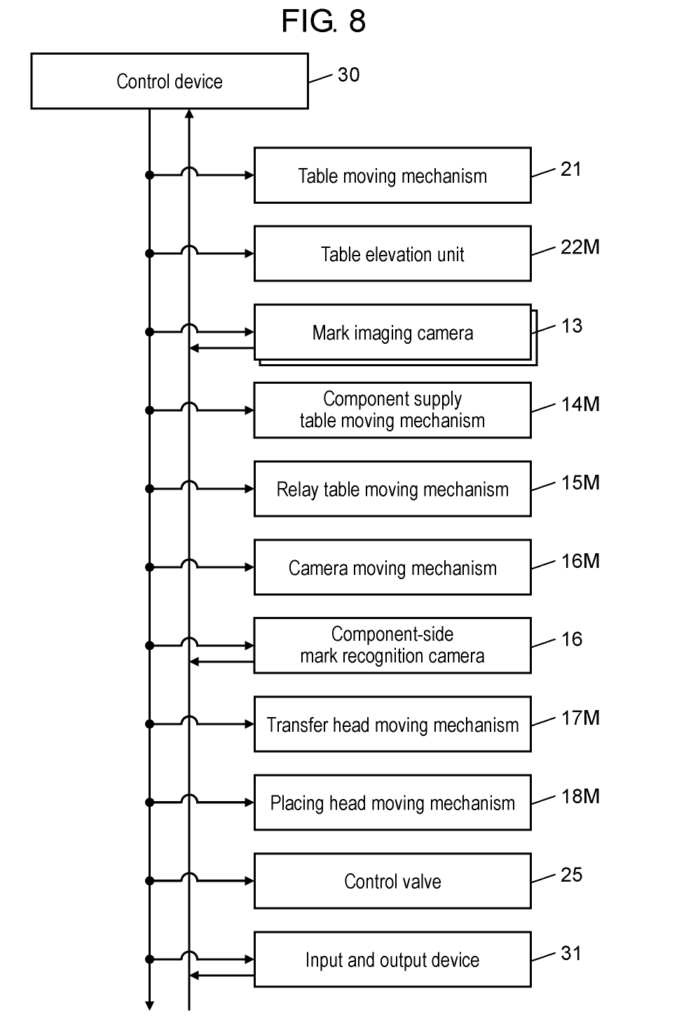

In FIG. 8, control device 30 included in component placing apparatus 1 performs each control of the movement of table base 22 (that is, of board holding table 23 and backup table 24) by table moving mechanism 21 in the horizontal plane direction, the movement of board holding table 23 by table elevation unit 22M in the Z-axis direction, imaging by two mark imaging cameras 13, the movement of component supply table 14 by component supply table moving mechanism 14M in the horizontal plane direction, the movement of relay table 15 by relay table moving mechanism 15M in the Y-axis direction, and position correction thereof in the X-axis direction.

Control device 30 performs each control of the movement of component-side mark recognition camera 16 by camera moving mechanism 16M in the X-axis direction, imaging by component-side mark recognition camera 16, the movement of transfer head 17 by transfer head moving mechanism 17M in the Y-axis direction and in the Z-axis direction, the movement of placing head 18 by placing head moving mechanism 18M in the Z-axis direction, and the rotation thereof around the Z-axis. Furthermore, control device 30 performs each control of the suction of center region 2C of board 2 by board holding table 23 by control valve 25, and the suction of end region 2R of board 2 by backup table 24.

In FIG. 8, image information obtained by being taken an image by two mark imaging cameras 13, and image information obtained by being imaged by component-side mark recognition camera 16 are respectively sent to control device 30. Control device 30 is connected to input and output device 31 such as a touch panel, and operator OP can perform a predetermined input into component placing apparatus 1 through input and output device 31. Operator OP can obtain various types of information regarding component placing apparatus 1 through input and output device 31.

Next, a procedure for executing placing work of component 3 on board 2 by component placing apparatus 1 will be described. When component 3 is placed on board 2 by component placing apparatus 1, operator OP performs a predetermined work starting operation from input and output device 31. When operator OP performs the work starting operation from input and output device 31, table moving mechanism 21 is controlled by control device 30 to be operated, and to position table base 22 at a predetermined position (referred to as a board receiving position) on a front left side of base 11 (FIG. 1). When table base 22 is positioned at the board receiving position, board holding table 23 and backup table 24 receive and hold board 2 supplied from the outside of component placing apparatus 1 (board holding step).

In the board holding step, table elevation unit 22M is operated and the height adjustment of board holding table 23 with respect to backup table 24 is performed so as to hold board 2 in the horizontal posture (horizontal posture holding step). Control valve 25 is controlled by control device 30 to be operated, and the suction force is generated on the upper surface of board holding table 23 and the upper surface of backup table 24 (suction step). Therefore, the lower surface of center region 2C of board 2 is sucked and held on board holding table 23, and the lower surface of component placing region 2a of board 2 is supported and sucked by backup table 24.

Thus, in a case where warping occurs in center region 2C of board 2, the warping is corrected and also in a case where warping occurs in end region 2R of board 2, the warping is corrected. As described above, since the warping of end region 2R of board 2 is corrected, component placing region 2a provided in end region 2R is positioned in a plane parallel to the upper surface of backup table 24, and two board-side marks 2m positioned in end region 2R are also positioned in the plane parallel to the upper surface of backup table 24.

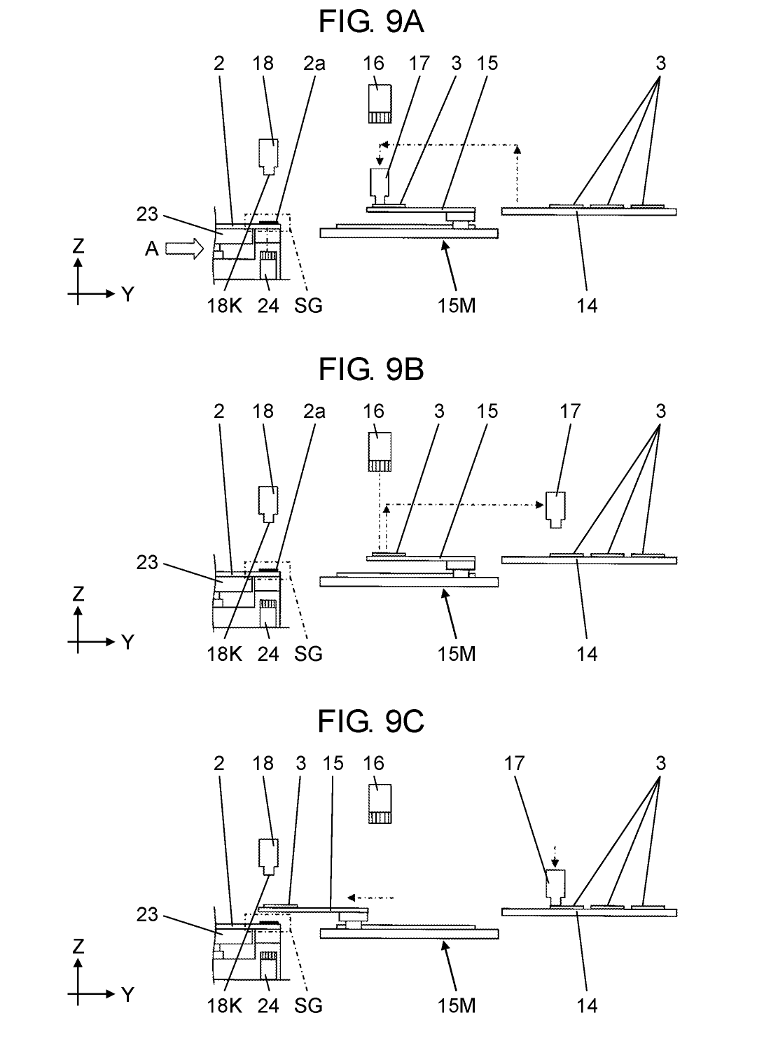

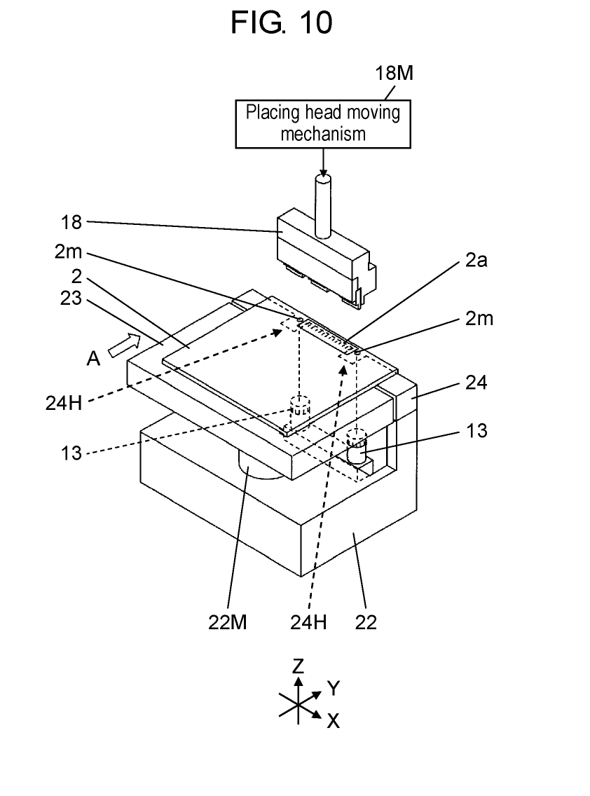

When board 2 is held by board holding table 23 and backup table 24, table moving mechanism 21 moves table base 22 to a position rearward from the board receiving position (arrow A illustrated in FIGS. 9A and 10), thereby positioning component placing region 2a of board 2 at working position SG (FIG. 9A. Work position moving step).

When component placing region 2a of board 2 is positioned at working position SG, two board-side marks 2m of board 2 are positioned above two mark imaging cameras 13 (FIGS. 9A and 10). Therefore, two mark imaging cameras 13 can take an image of two board-side marks 2m from below through two cutout portions 24H provided in backup table 24 (FIG. 10), and two mark imaging cameras 13 take an image of two board-side marks 2m (board-side mark imaging step).

Two mark imaging cameras 13 transmit image data obtained by imaging to control device 30. Then, control device 30 performs image recognition based on the transmitted image data, and calculates respective positional shift of board 2 in the X-axis direction, in the Y-axis direction, and the rotating direction around the Z-axis in a state where component placing region 2a is positioned at working position SG (board-side positional shift calculating step).

In component placing apparatus 1 in the embodiment, end region 2R of board 2 is sucked and is in close contact with the upper surface of backup table 24, the end region of board 2 is planarized, and thereby two board-side marks 2m are positioned in the plane parallel to the upper surface of backup table 24. Therefore, the recognition accuracy of board-side marks 2m by mark imaging cameras 13 is extremely high.

In component placing apparatus 1 in the embodiment, cutout portions 24H penetrating backup table 24 vertically are provided. Therefore, mark imaging cameras 13 of which the imaging field of view faces upward can take an image of board-side marks 2m of board 2 positioned at working position SG while maintaining a state where end region 2R of board 2 is continuously supported by backup table 24.

When two mark imaging cameras 13 take an image of two board-side marks 2m and control device 30 calculates the position shift of board 2 at working position SG, transfer head 17 is moved above component supply table 14, is lowered, and sucks component 3. Transfer head 17 is moved above relay table 15 and is lowered in a state of sucking component 3, and transfers (temporarily places) component 3 on relay table 15 positioned at the first position by relay table moving mechanism 15M (FIG. 9A. Component temporarily placing step).

After placing component 3 temporarily on relay table 15, transfer head 17 moves upward and moves further rearward therefrom to evacuate from the upper region of relay table 15 (imaging region by component-side mark recognition camera 16). Next, transfer head 17 moves above component 3 to be transferred to relay table 15 (FIG. 9B). When transfer head 17 evacuates from the upper region of relay table 15, component-side mark recognition camera 16 is driven by camera moving mechanism 16M and moves in the X-axis direction to take an image of two component-side marks 3m included in component 3 (FIG. 9B. Component-side mark imaging step).

When component-side mark recognition camera 16 takes an image of component-side marks 3m, the image information obtained by the imaging thereof is sent to control device 30, and control device 30 grasps the position of component 3 on relay table 15 from the image information of two component-side marks 3m sent from component-side mark recognition camera 16. In a case where the position of component 3 on relay table 15 in the X-axis direction is shifted from a regular position, control device 30 calculates a positional shift amount from the regular position (component-side positional shift calculating step).

When control device 30 grasps the position of component 3 on relay table 15, relay table moving mechanism 15M moves relay table 15 from the first position to the second position (FIG. 9C. Relay table moving step). In the relay table moving step, when moving relay table 15 from the first position to the second position, control device 30 moves relay table 15 in the X-axis direction, thereby correcting the positional shift amount of component 3 in the X-axis direction on relay table 15 calculated in the positional shift calculating step.

Component 3 on relay table 15 is in a state of being positioned above working position SG, that is, directly under placing head 18 by the relay table moving step. Simultaneously with this, transfer head 17 descends from above component 3 to be placed on relay table 15 and sucks component 3 (FIG. 9C).

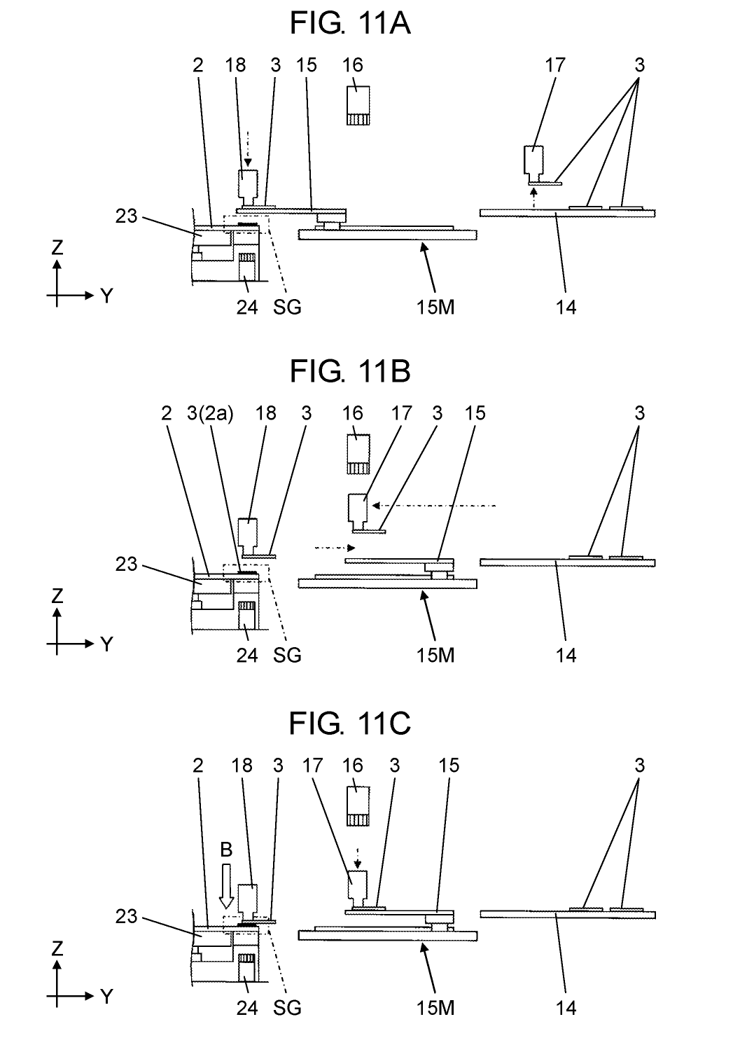

When relay table 15 is positioned at the second position, placing head 18 descends. After component suction unit 18K abuts against component 3 on relay table 15 and sucks component 3 thereof (FIG. 11A), component suction unit 18K rises and picks up component 3 (pickup step).

When placing head 18 picks up component 3, relay table 15 moves to the first position and evacuates from above working position SG (relay table evacuating step). Therefore, component 3 which is picked up by placing head 18 is in a state of being positioned above component placing region 2a (thermosetting resin tape JT) (FIG. 11B). Meanwhile, transfer head 17 moves above relay table 15 moved to the first position (FIG. 11B).

When relay table 15 evacuates from above working position SG, position correction is performed so that two board-side marks 2m and two component-side marks 3m are matched in a plan view based on the positional shift amount on board 2 side calculated in the board-side positional shift calculating step and the positional shift amount on component 3 side calculated in the component-side positional shift calculating step. Specifically, table moving mechanism 21 moves table base 22 (that is, board 2), and placing head moving mechanism 18M rotates placing head 18 (that is, component 3) around the Z-axis (position correcting step).

In component placing apparatus 1 of the embodiment, board holding table 23 holding the lower surface of center region 2C of board 2 and backup table 24 supporting the lower surface of end region 2R of board 2 are integrally moved. Therefore, it is possible to perform the position correction while maintaining a state where board 2 is in contact with backup table 24. In a case where the component placing apparatus of the related art which places end region 2R of board 2 on the backup stage provided to be fixed to the base, descends the placing head from above the backup stage, and places component 3 on board 2, during the correction described above, it is necessary to raise the board (lifts the board from the backup stage) and again lowers the board, but in component placing apparatus 1 of the embodiment, such a step is unnecessary.

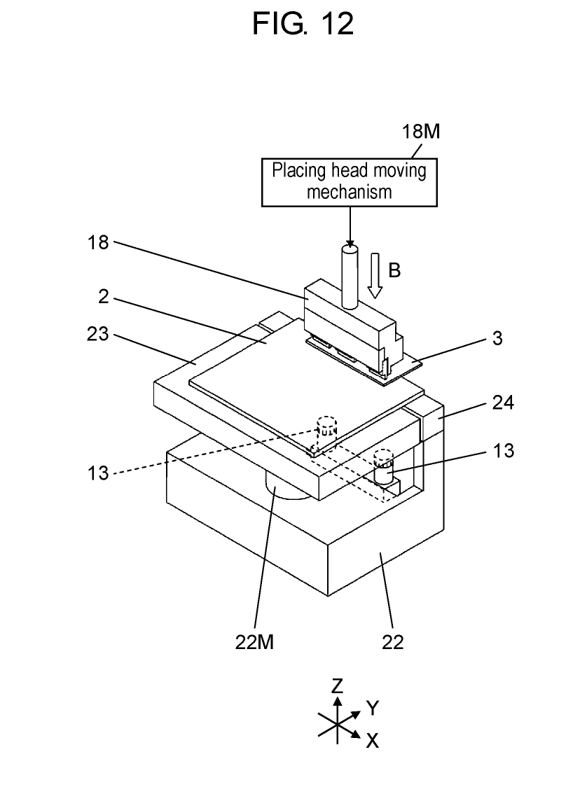

When the position correction is performed so that two board-side marks 2m and two component-side mark 3m match each other in a plan view, placing head moving mechanism 18M descends placing head 18 from above working position SG. Therefore, placing head 18 presses component 3 against component placing region 2a of board 2 supported by backup table 24 from above, and places component 3 on board 2 (component placing step. Arrow B illustrated in FIGS. 11C and 12). In this case, a pressing force of component 3 by placing head 18 acts on backup table 24. Simultaneously with this, transfer head 17 places (transfers) sucked component 3 on relay table 15 positioned at the first position (FIG. 11C).

When component 3 is placed on board 2, placing head moving mechanism 18M raises placing head 18. When placing head 18 is raised, table moving mechanism 21 moves table base 22 in the horizontal plane, and positions table base 22 at a predetermined position (referred to as a board delivery position) on a front right side of base 11. When table base 22 is positioned at the board delivery position, control device 30 operates to release the suction force in board holding table 23 and the suction force in backup table 24 and then delivers board 2 on which component 3 is placed to a mechanism outside component placing apparatus 1 (board delivery step). Therefore, placing work of component 3 for one sheet of board 2 is completed.

As described above, in component placing apparatus 1 of the embodiment, the lower surface of center region 2C of board 2 made of the film-shaped member is held by board holding table 23, and the lower surface of end region 2R (region in which component placing region 2a is provided) of board 2 is supported by backup table 24. After board holding table 23 is moved together with backup table 24 and component placing region 2a is positioned at working position SG, placing head 18 presses component 3 against component placing region 2a from above to place component 3 on board 2. Meanwhile, suction mechanism 27 sucks end region 2R of board 2 which is supported by backup table 24 through the plurality of suction ports 24S opened to the upper surface of backup table 24. Therefore, even in a case where warping occurs in end region 2R of board 2 made of the film-shaped member, the warping is corrected and component placing region 2a assumes as a planar state free from warping. Therefore, it is possible to accurately place component 3 on component placing region 2a of board 2 made of the film-shaped member.

In component placing apparatus 1 of the embodiment, backup table 24 includes suction block 24K made of the porous material, and the plurality of suction ports 24S are constituted of pores of the porous material constituting suction block 24K which is provided to be exposed to the upper surface of backup table 24. End region 2R of board 2 is sucked through the pores of the porous material, a hole diameter of the pore of the porous material is, for example, approximately 60 μm, and is sufficiently small compared to a thickness of board 2. Therefore, the surface of board 2 is not pulled into the pores (suction ports 24S), or voids are not generated in board 2. That is, in the embodiment, the hole diameter of each of the plurality of suction ports 24S formed on the upper surface of backup table 24 has a size such that voids are not generated in board 2 to be sucked. Specifically, besides having the hole diameter of each of the plurality of suction ports of approximately 60 μm, the hole diameter of 40 μm to 500 μm can be also used.

In the embodiment described above, suction ports 23S of board holding table 23 are constituted of the pores of the porous material constituting suction block 23K provided in board holding table 23, but a plurality of suction holes opening on the upper surface of board holding table 23 may be provided and are connected to suction pipe line 23C inside board holding table 23 without providing suction block 23K made of the porous material. Even with such a configuration, board 2 can be sucked to board holding table 23 as in the case of the embodiment described above.

### First Modification Example

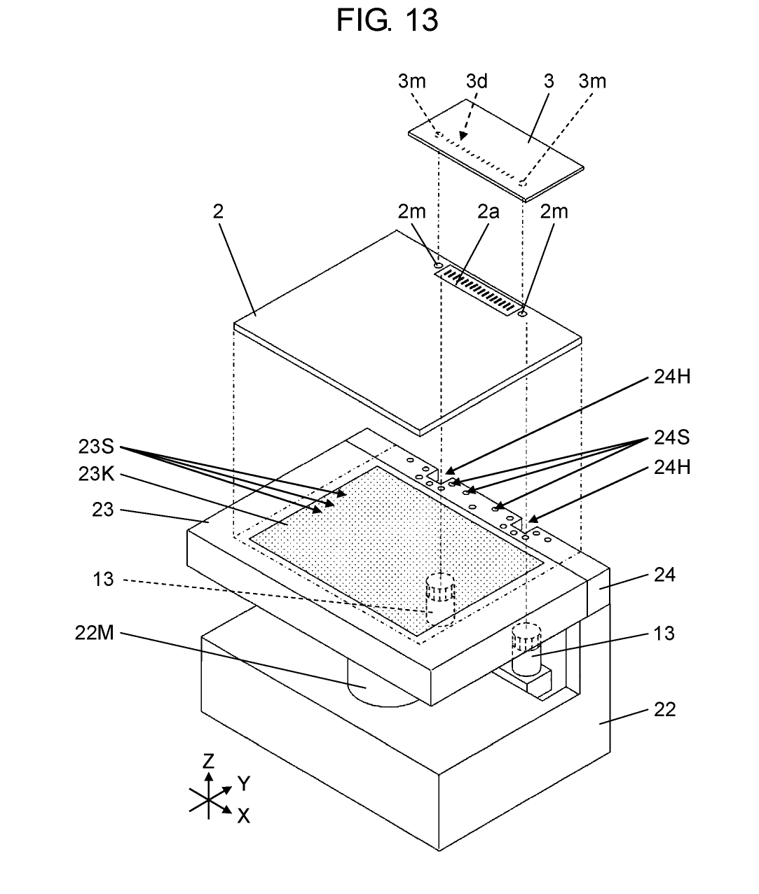

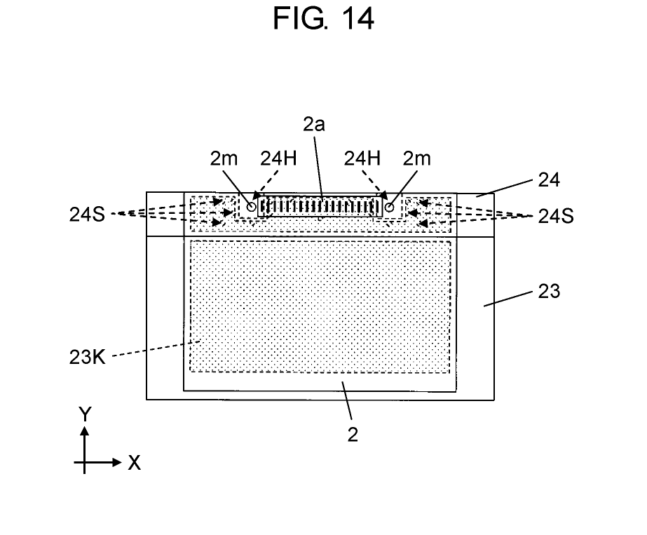

FIGS. 13 and 14 illustrate a first modification example of component placing apparatus 1 of the embodiment. In the first modification example, instead of providing suction block 24K made of the porous material in backup table 24, a large number of (that is, a plurality of) holes are provided on the upper surface of backup table 24 to be penetrated and are suction ports 24S, and suction ports 24S are configured to be connected to suction pipe line 24C inside backup table 24.

Also in the component placing apparatus of the first modification example as described above, when the suction force is generated at suction ports 24S, the lower surface of end region 2R (region in which component placing region 2a is provided) of board 2 is sucked and is in close contact with the upper surface of backup table 24 as in component placing apparatus 1 of the embodiment described above. Therefore, in a case where warping occurs in end region 2R of board 2 made of the film-shaped member, the warping is corrected, and it is possible to accurately place component 3 on board 2 made of the film-shaped member.

In the first modification example, the hole diameter of each suction port 24S is set to a such a size that board 2 to be sucked is not pulled into suction port 24S, or voids are not generated in board 2. Specifically, the hole diameter of suction port 24S is approximately 0.3 mm or less. In this way, although it is necessary to penetrate suction ports 24S, or the like, the same effect as in the embodiment described above can be obtained.

In the case of the first modification example, it is preferable that the plurality of suction ports 24S are provided in a region for sucking a periphery of cutout portions 24H with a higher density than a region for sucking a part other than the periphery of cutout portions 24H (FIGS. 13 and 14). Therefore, it is possible to flatten regions in the vicinity of two board-side marks 2m in end region 2R of board 2, and to improve recognition accuracy of board-side marks 2m by mark imaging cameras 13.

### Second Modification Example

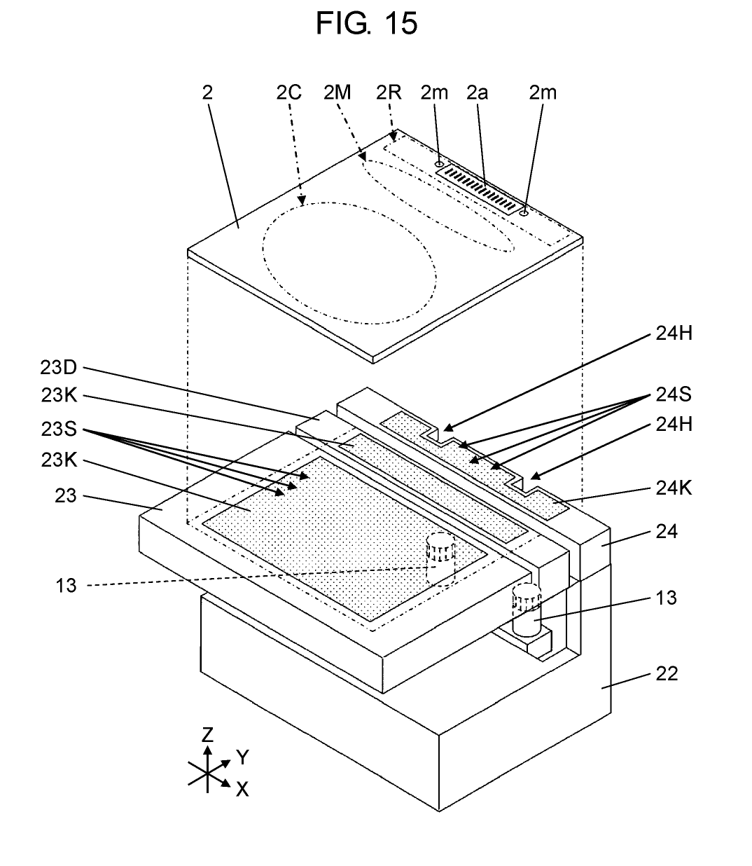

FIG. 15 illustrates a second modification example of component placing apparatus 1 of the embodiment. The second modification example illustrates an example in which there is a concern that intermediate portion 2M of board 2 is bent between a large gap between board holding table 23 and backup table 24. As illustrated in FIG. 15, support member 23D is provided between board holding table 23 and backup table 24. That is, support member 23D supports a lower surface of intermediate portion 2M of board 2. In the second modification example, suction block 23K made of the porous material is also provided on an upper portion of support member 23D in a state where an upper surface thereof is exposed. The lower surface of intermediate port 2M of board 2 is supported by the upper surface of suction block 23K, and the lower surface of intermediate portion 2M of board 2 is sucked through pores of a porous material constituting suction block 23K.

In the second modification example, support member 23D can be raised and lowered as in the case of board holding table 23, support member 23D is configured to hold board 2 in the horizontal posture together with board holding table 23 and backup table 24. Even with such a configuration, as in the case of the embodiment and the first modification example described above, in a case where warping occurs in end region 2R of board 2 made of the film-shaped member, the warping is corrected and it is possible to accurately place component 3 on board 2 made of the film-shaped member.

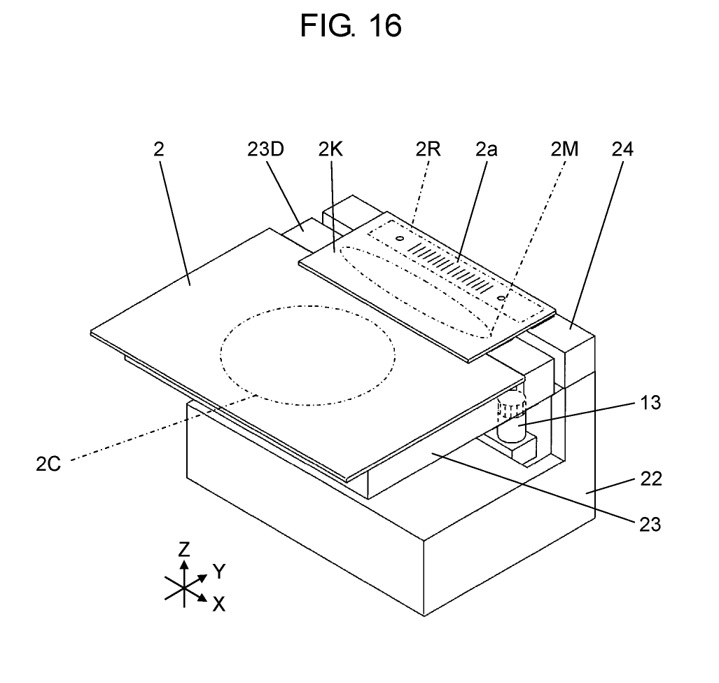

As illustrated in FIG. 16, in a case where board 2 has extended portion 2K (for example, another board made of the film-shaped member attached to end region 2R), and a film-shaped component or the like is further attached to end region 2R of extended portion 2K, if center region 2C of board 2 is held by board holding table 23 and extended portion 2K of board 2 is held by support member 23D, it is possible to attach the film-shaped component or the like to end region 2R of board 2 (here, of extended portion 2K) in an extremely stable state.

### CONCLUSION

As described above, component placing apparatus 1 of the embodiment is a component placing apparatus for placement of component 3 on board 2, board 2 having center region 2C and end region 2R in which component placing region 2a provided. Component placing apparatus 1 of the embodiment includes board holding table 23 which holds board 2 on the lower surface of center region 2C, backup table 24 which holds board 2 on the lower surface of the end region, suction mechanism 27 comprising suction ports 24S opened on the upper surface of backup table 24, suction mechanism 27 sucking board 2 at end region 2R through suction ports 24, table moving mechanism 21 which moves both board holding table 23 to position component placing region 2a at predetermined working position SG, and placing head 18 which picks up component 3 and presses component 3 from above to component placing region 2a to place component 3 on board 2.

The method for placing a component of the embodiment is a method for placing a component by component placing apparatus 1 which places component 3 on board 2, board 2 having center region 2C and end region 2R in which component placing region 2a provided. The method for placing a component of the embodiment includes the board holding step of holding board 2 supplied from the outside of component placing apparatus 1 by board holding table 23 which holds board 2 on the lower surface of center region 2C of board 2 and backup table 24 which holds board 2 on the lower surface of end region 2R, the suction step of sucking board 2 at end region 2R by suction mechanism 27 through the plurality of suction ports 24S opened on the upper surface of backup table 24, the working position moving step of moving both board holding table 23 and backup table 24 to position component placing region 2a at predetermined working position SG, and the component placing step of picking up component 3 by placing head 18 and pressing component 3 from above to component placing region 2a to place component 3 on board 2.

The disclosure provides the component placing apparatus and the method for placing a component capable of accurately placing the component on the board made of the film-shaped member.

What is claimed is:

1. A component placing apparatus for placement of a component on a board, the board having a center region and end region in which a component placing region is provided, the apparatus comprising:
a board holding table which holds the board on a lower surface of the center region;
a backup table which holds the board on a lower surface of the end region;
a suction mechanism comprising suction ports opened on an upper surface of the backup table, the suction mechanism sucking the board at the end region through the suction ports;
a table moving mechanism which moves both the board holding table and the backup table to position the component placing region at a predetermined working position; and
a placing head which picks up the component and presses the component from above to the component placing region to place the component on the board.

2. The component placing apparatus of claim 1, wherein
the table moving mechanism moves both the board holding table and the backup table such that both the board holding table and the backup unit hold the board horizontally.

3. The component placing apparatus of claim 1,
wherein the plurality of suction ports are constituted by pores of a porous material provided so as to be exposed on the upper surface of the backup table.

4. The component placing apparatus of claim 1,
wherein the plurality of suction ports are constituted by a plurality of holes and a hole diameter of each of the plurality of suction ports has a size that does not generate voids in the board to be sucked.

5. The component placing apparatus of claim 1,
wherein the backup table comprises a cutout portion penetrating through the backup table, and the component placing apparatus further comprising a mark imaging camera, of which an imaging field of view faces upward, takes an image of a board-side mark of the board positioned at the working position through the cutout portion.

6. The component placing apparatus of claim 1
wherein the backup table comprises a cutout portion penetrating through the backup table, and the component placing apparatus further comprising a mark imaging camera, of which an imaging field of view faces upward, takes an image of a board-side mark of the board positioned at the working position through the cutout portion, and the plurality of suction ports are provided in a region for sucking a periphery of the cutout portion at a higher density than a region for sucking a portion other than the periphery of the cutout portion.

7. The component placing apparatus of claim 1, further comprising:
a support member which is provided between the board holding table and the backup table, and holds the board on a lower surface of an intermediate port,
wherein the support member sucks and holds the board on an upper surface, and
wherein the support member holds the board horizontally together with the board holding table and the backup table.

8. A method for placing a component by a component placing apparatus which places a component on a board, the board having a center region and an end region in which a component placing region is provided, the method comprising:
a board holding step of holding the board supplied from an outside of the component placing apparatus by a board holding table which holds the board on a lower surface of the center region and a backup table which holds the board on a lower surface of the end region;
a suction step of sucking the board at the end region by a suction mechanism through a plurality of suction ports opened on an upper surface of the backup table;
a working position moving step of moving both the board holding table and backup table to position the component placing region at a predetermined working position; and
a component placing step of picking up the component by a placing head and pressing the component from above to the component placing region to place the component on the board.

9. The method of claim 8,
wherein the working position moving step of moving both the board holding table and backup table such that the board holding table and backup table hold the board horizontally.
